(19) United States
(12) Patent Application Publication
(10) Pub. No.: US 2025/0233108 A1
(43) Pub. Date: Jul. 17, 2025

(54) PLURALITY OF ADVANCED MULTILEVEL CIRCUIT ATTACHMENTS

(71) Applicant: Tokyo Electron Limited, Tokyo (JP)

(72) Inventors: Mark L. Gardner, Austin, TX (US); Henry Jim Fulford, Marianna, FL (US); Partha Mukhopadhyay, Oviedo, FL (US)

(21) Appl. No.: 18/412,067

(22) Filed: Jan. 12, 2024

(51) Int. Cl. H01L 23/00; H01L 21/683; H01L 21/762; H01L 21/768

(52) U.S. Cl. CPC H01L 24/97; H01L 21/6835; H01L 21/76224; H01L 21/76898; H01L 2224/97; H01L 2924/1434

(57) ABSTRACT

According to an embodiment, a semiconductor structure includes a first wafer comprising a device region, a first substrate, and a first bonding layer, the first substrate arranged in between the device region and the first bonding layer and having a plurality of vias coupling the device region to a surface of the first substrate attached to the first bonding layer. The first wafer having first cavities establishing a localized area designated for singulation of the first wafer. The structure further includes a sacrificial wafer attached to the first bonding layer of the first wafer. The first cavities extending through the second bonding layer of the sacrificial wafer. The first cavities extend through a first protective layer. A second protective layer is attached to the sacrificial wafer. Second cavities are vertically aligned with the first cavities and extending through the second protective layer and partially through the second substrate.

### TECHNICAL FIELD

The present disclosure generally relates to die attachment and, in particular embodiments, to a plurality of advanced multilevel circuit attachments.

### BACKGROUND

Die attachment, commonly used in the microelectronics and semiconductor industries, involves bonding a chip or die to a substrate or package. This process is a critical stage in the construction of semiconductor devices, as it affects both the performance and reliability of the final product. Die attachment involves using adhesives, eutectic alloys, or solder to bond the die to the substrate, leaving electrical connections accessible for the next stages of the manufacturing process.

Large but very thin dies pose a specific challenge within the die attachment process. Given their size, these can warp or crack due to stresses induced during the bonding process or subsequent thermal cycling. Further, the thinness of the dies can make handling and positioning them more difficult during manufacturing.

Three-dimensional (3D) die attachment is a technique introduced to overcome limitations related to thin, large dies. This process, also known as die stacking or 3D packaging, involves placing several chips vertically on top of one another to increase the package density and improve performance. This differs from the traditional method of placing dies side-by-side on a substrate or board.

3D die attachment can minimize interconnect length, reduce power consumption, and increase speed. This method produces more compact packages, allowing greater processing power in smaller devices. However, it also raises challenges regarding heat dissipation, signal integrity, and the complexity of testing and failure analysis.

The continuing trend towards miniaturization and the need for improved performance and functionality in electronic devices is driving advancements and innovations in die attachment techniques, including those involving large, thin dies and three-dimensional die attachments.

### SUMMARY

Technical advantages are generally achieved by embodiments of this disclosure, which describe a plurality of advanced multilevel circuit attachments.

A first aspect relates to a method for assembling a package. The method includes forming first cavities in a first wafer comprising a device region formed on a first substrate, the first substrate having a plurality of vias coupling the device region to an exposed surface of the first substrate, the first cavities establishing a localized area designated for singulation of the first wafer; filling the first cavities with a dielectric fill; depositing a bonding layer on the exposed surface of the device region; attaching a sacrificial wafer to the first wafer at the bonding layer, the sacrificial wafer comprising a second substrate; attaching protective layers to the exposed surface of the first substrate and the exposed surface of the sacrificial wafer; forming second cavities at the exposed surface of the sacrificial wafer, the second cavities partially extending through the second substrate with an overlapping footprint with the first cavities; forming third cavities at the first cavities to remove the dielectric fill and extending the third cavities to a cavity region at the bonding layer; and placing the first wafer attached to the sacrificial wafer on a curved surface and applying pressure on the first wafer to form chiplets, each chiplet comprising individual dies from the first wafer.

A second aspect relates to a method for chiplet separation. The method includes forming first cavities in a first wafer comprising a device region formed on a first substrate, the first substrate having a plurality of vias coupling the device region to an exposed surface of the first substrate, the first cavities establishing a localized area designated for singulation of the first wafer; filling the first cavities with a bonding material; depositing a bonding layer on the exposed surface of the device region; attaching a sacrificial wafer to the first wafer at the bonding layer, the sacrificial wafer comprising a second substrate; attaching protective layers to the exposed surface of the first substrate; forming second cavities at the exposed surface of the sacrificial wafer, the second cavities partially extending through the second substrate, the second cavities vertically aligned with the first cavities; forming third cavities at the first cavities to remove the bonding material and extending the third cavities to a cavity region at the bonding layer; and separating portions of the first substrate into chiplets, each chiplet defined by the third cavities and supported by a corresponding portion of the sacrificial wafer.

A third aspect relates to a semiconductor structure. The semiconductor structure includes a first wafer comprising a device region, a first substrate, and a first bonding layer, the first substrate arranged in between the device region and the first bonding layer, the first substrate having a plurality of vias coupling the device region to a surface of the first substrate attached to the first bonding layer, the first wafer having first cavities establishing a localized area designated for singulation of the first wafer; a sacrificial wafer comprising a second substrate and a second bonding layer, the second bonding layer attached to the first bonding layer of the first wafer, the first cavities extending through the second bonding layer of the sacrificial wafer; a first protective layer attached to the device region of the first wafer, the first cavities extending through the first protective layer; a second protective layer attached to the sacrificial wafer at the second substrate; and second cavities vertically aligned with the first cavities, the second cavities extending through the second protective layer and partially through the second substrate.

A fourth aspect relates to a method for bonding a chiplet to a device structure. The method includes forming first cavities in a first wafer comprising a device region formed on a first substrate, the first substrate having a plurality of vias coupling the device region to an exposed surface of the first substrate, the first cavities establishing a localized area designated for singulation of the first wafer; filling the first cavities with a dielectric material or a bonding material; depositing a bonding layer on the exposed surface of the device region; attaching a sacrificial wafer to the first wafer at the bonding layer, the sacrificial wafer comprising a second substrate; forming second cavities at the exposed surface of the sacrificial wafer, the second cavities partially extending through the second substrate, the second cavities vertically aligned with the first cavities; forming third cavities at the first cavities to remove the dielectric material or the bonding material and extending the third cavities to a cavity region at the bonding layer; separating portions of the first substrate into chiplets, each chiplet defined by the third cavities and supported by a corresponding portion of the sacrificial wafer; stacking a chiplet on to the device structure to form a three-dimensional integrated circuit; and removing the sacrificial wafer and bonding layer after forming the chiplet, wherein the sacrificial wafer is decoupled from the chiplet using a laser beam or removed from the chiplet using an infrared source.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 illustrates a cross-sectional view of an embodiment three-dimensional integrated circuit (3D IC);

FIGS. 2A-J illustrate cross-sectional views of an embodiment process flow for forming the 3D IC;

FIGS. 3A-J illustrate cross-sectional views of an alternative embodiment process flow for forming the 3D IC;

FIG. 4 illustrates a flow chart of an embodiment method that details the process that facilitates die separation and the sequential pick and place of device circuits for advanced multi-level circuit attachments employing a cavity filled with dielectric; and

FIG. 5 illustrates a flow chart of an embodiment method that details the process that facilitates die separation and the sequential pick and place of device circuits for advanced multi-level circuit attachments employing a cavity filled with bonding material.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

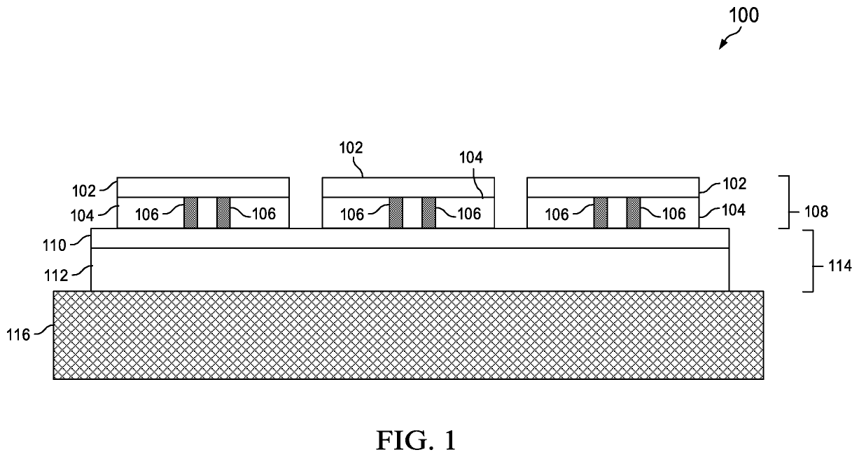

For simplicity of the discussion, when a reference is made to the backside of a structure (or layer), it is meant to convey to the reader the surface of the structure nearest to the wafer chuck 116, as shown in the various figures. For example, regarding FIG. 1, the backside of the second device region 110 refers to the surface at the boundary between the second device region 110 and the second substrate 112.

Additionally, when reference is made to the top surface of a structure (or layer), it is meant to convey to the reader the surface of the structure furthest away from the wafer chuck 116, as shown in the various figures. For example, regarding FIG. 1, the top surface of the second device region 110 refers to the surface at the boundary between the second device region 110 and the first wafer 108.

In embodiments, a three-dimensional (3D) die attachment method with a disposable substrate underlayer is disclosed. The proposed method significantly enhances the manufacturing process in 3D (i.e., stacked) integrated circuits. This method enables the fabrication of thin and considerably large die with a thickness of less than 40 μm. The thin die can be diced using the proposed method, simplifying picking and placing it to a desired height. Primarily facilitated by the thinness of the die, this method discloses an efficient stacking process that can facilitate forming a 3D integrated circuit comprising a stack of N semiconductor dies or chips interconnected with 3D electrical interconnects, where Nis an integer greater than one.

Aspects of this disclosure allow for forming a thin die with increased density of the 3D circuit without leading to an undesirable increase in the device height. The increased density significantly contributes to the overall efficiency and performance of the device, while the preserved compactness aids in the device's practical application and usability. Therefore, the extremely thin die achieves a higher density of 3D integrated circuits and maintains a check on the multiple circuit device heights.

FIG. 1 illustrates a cross-sectional view of an embodiment three-dimensional integrated circuit (3D IC) 100. 3D IC 100 includes a first wafer (wafer 1) 108 and a second wafer (wafer 2) 114 arranged as vertically stacked integrated active electronic components. In embodiments, the first wafer 108 and the second wafer 114 are independently formed. Embodiments of this disclosure provide a process flow for stacking the first wafer 108 on the second wafer 114 to form the 3D IC 100. In embodiments, the second wafer 114 is a base circuit, such as a microprocessor, a 3D memory stack, or the like.

The first wafer 108 includes a first device region 102. The thinned, first wafer 108 may be less than 40 microns thick, for example, 10 μm to 40 μm, and 5 μm to 40 μm in one embodiment. The first device region 102 may be 0.2 microns thick, for example, 0.1 μm to 0.4 μm, and 0.05 μm to 0.3 μm in one embodiment.

The second wafer 114 includes a second device region 110. The second wafer 114 may be 0.05 microns thick, for example, 0.03 μm to 0.1 μm, and 0.01 μm to 0.2 μm in one embodiment. The second device region 110 may be 0.2 microns thick, for example, 0.1 μm to 0.4 μm, and 0.05 μm to 0.3 μm in one embodiment.

Although not shown, 3D IC 100 may include additional wafers, each with one or more device regions, which may be integrated vertically or horizontally within a single semiconductor. The second wafer 114 is shown to be placed on a wafer chuck 116.

The first wafer 108 includes a first substrate 104. The second wafer 114 includes a second substrate 112. The first substrate 104 and the second substrate 112 form a base or foundation upon which the first device region 102 and the second device region 110, respectively, form. In embodiments, the first substrate 104 and the second substrate 112 are formed from a pure single crystal material, such as silicon. The thinned, first substrate 104 may be less than 40 microns thick, for example, 10 μm to 40 μm, and 5 μm to 40 μm in one embodiment. Second substrate 112 may be 500 microns thick, for example, 200 μm to 800 μm, and 100 μm to 900 μm in one embodiment.

The active components in the first device region 102 are conductively coupled to the active components in the second device region 110 through vias 106. In embodiments, vias 106 are through-silicon vias (TSVs), enabling them to stack and vertically interconnect multiple device regions, such as the first device region 102 and the second device region 110.

Vias 106 serve as conduits for signals and currents, bridging links between the first device region 102 and the second device region 110. Accordingly, the vias 106 link the components of the first device region 102, such as transistors and diodes, to components of the second device region 110.

Vias 106 are small openings or passageways that are etched or drilled into the first substrate 104 vertically extending from a first surface at the boundary of the first device region 102 and the first substrate 104 to an opposing second surface at the boundary of the second device region 110 and the first substrate 104.

Vias 106 are filled with a conductive material such as a metal like copper or tungsten. They usually take on cylindrical or tapered shapes, depending on their formation. Vias 106 can be formed through deposition, etching, and planarization to ensure precise volumes of conductive materials fill the cavity without causing defects.

The vertical integration of electronic components in the 3D IC 100 allows for shorter interconnections, resulting in faster signal processing and reduced power consumption. As such, 3D IC 100 can execute tasks more quickly and efficiently than its 2D counterpart. The compact structure of the 3D IC 100 can lead to a reduced footprint, resulting in higher levels of integration and, therefore, the fitting of more components into a smaller area. As a result, a host device using the 3D IC 100 can be made smaller, lighter, and more portable without sacrificing functionality and power. The shorter interconnection in the 3D IC 100 also means lower power consumption.

Moreover, the proximity of electronic components within the 3D IC 100 allows for more efficient heat dissipation, which in turn minimizes the chances of overheating and subsequently prolongs the life of the host device. In addition, the structure of the 3D IC 100 is conducive to heterogeneous integration. This allows different materials, devices, and signals (analog, digital, RF, etc.) to co-exist within a single chip. This ultimately enables the creation of more versatile and robust systems.

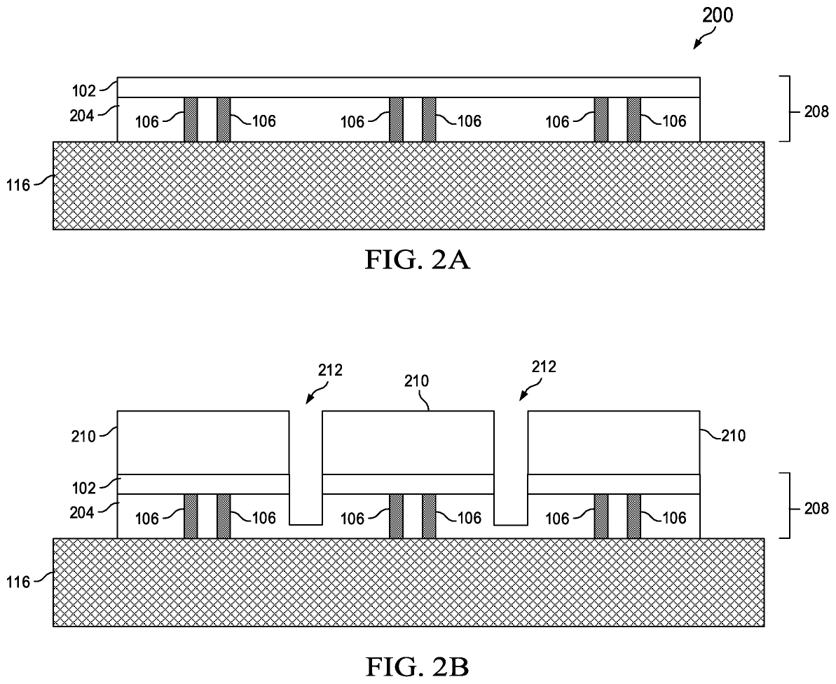

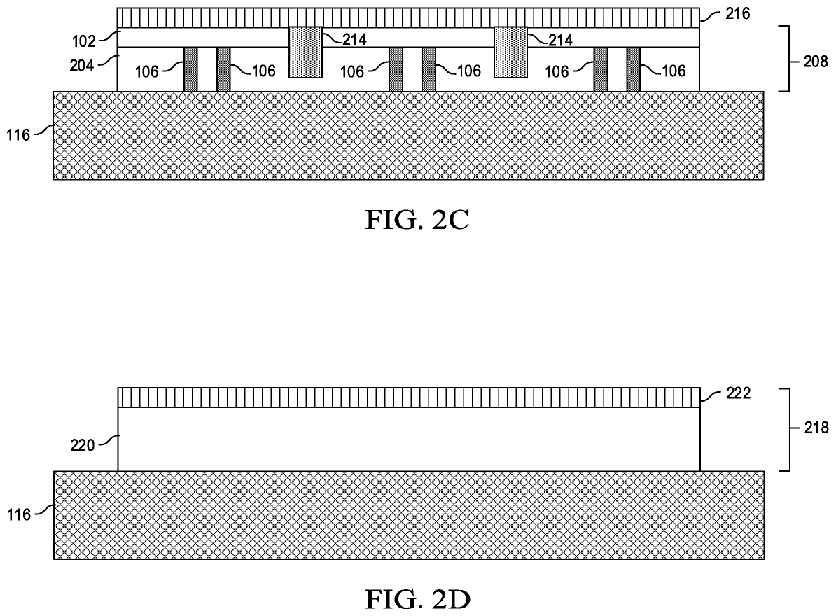

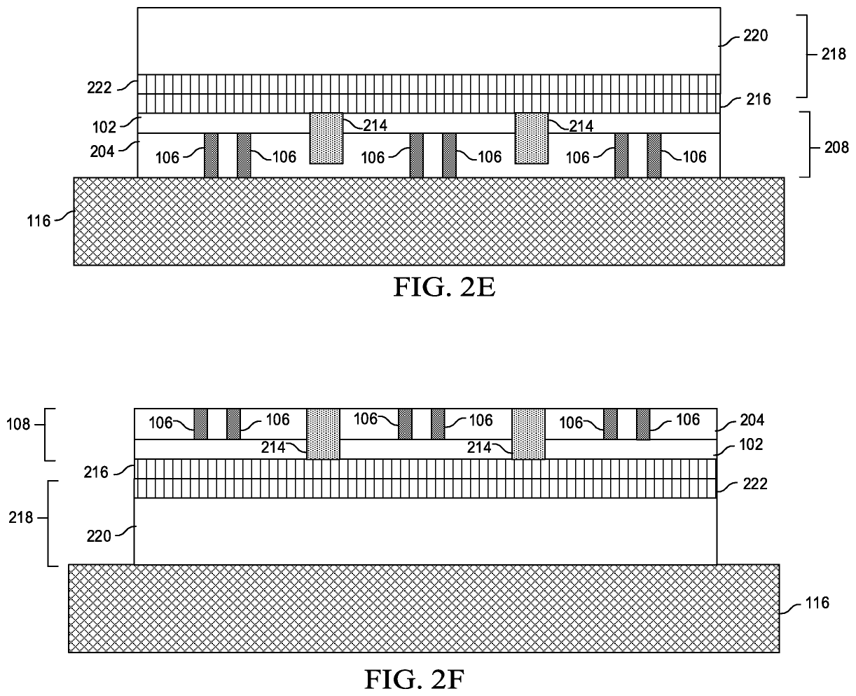

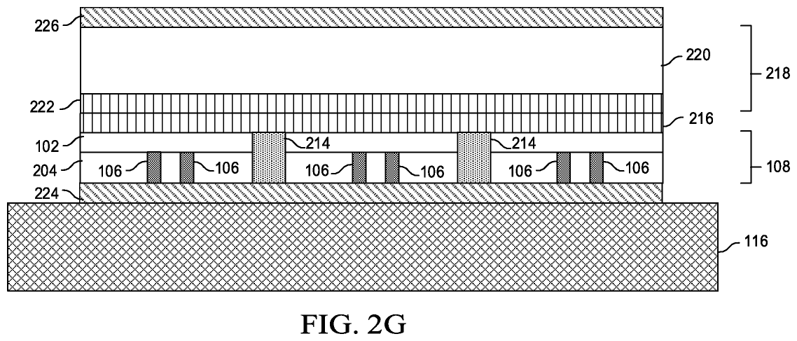

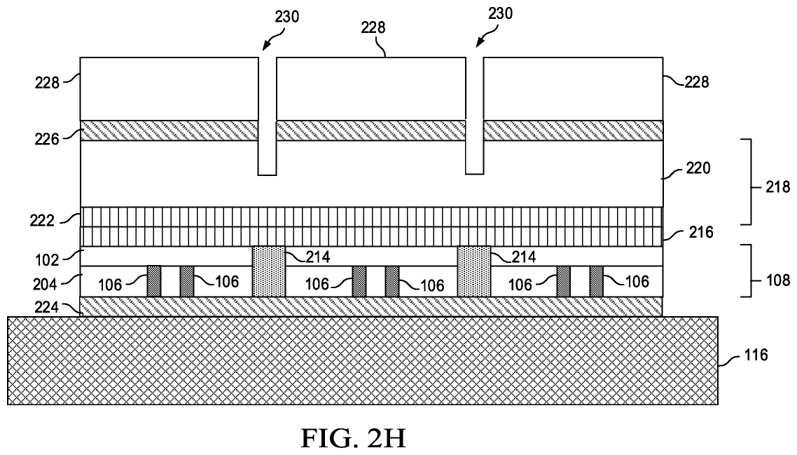

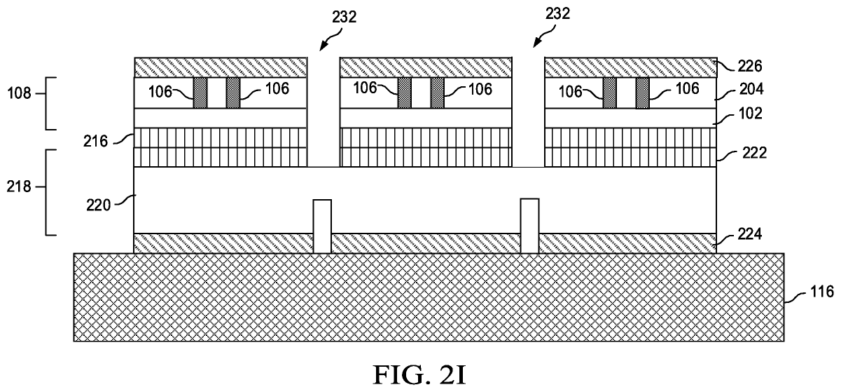

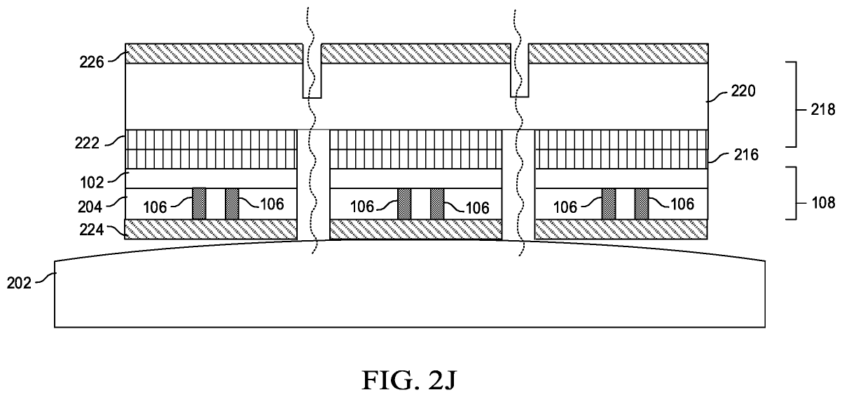

FIGS. 2A-J illustrate cross-sectional views of an embodiment process flow for forming the 3D IC 100. The example flow details the process that facilitates die separation and the sequential pick and place of device circuits for advanced multi-level circuit attachments employing a cavity filled with dielectric.

FIG. 2A illustrates the first wafer 208 as a solitary structure 200 placed on a wafer chuck 116. The first wafer 208 is identical to the first wafer 108 in FIG. 1, except that the first wafer 208 has a first substrate 204 thicker than the first substrate 104 in the first wafer 108. To distinguish between the first wafers and the substrates, the first substrate 104 and the first wafer 108 are denoted as such, derived from the first substrate 204 and the first wafer 208, having undergone a process that decreases its thickness. The first substrate 204 and the first substrate 104 represent the same structure. Likewise, the first wafer 208 and the first wafer 108 represent the same structure. However, the different labels highlight the state of the same structures before and after the thinning process. The first substrate 208 may be less than 40 microns thick, for example, 10 μm to 40 μm, and 5 μm to 40 μm in one embodiment.

In embodiments, the first wafer 208 includes the first device region 102, the first substrate 204, and vias 106 extending through the first substrate 204, which may (or may not) be arranged as shown. In embodiments, the first wafer 208 may include additional layers or components not shown. For example, the first device region 102 can include multiple stacks.

Generally, a device region, such as the first device region 102 and the second device region 110, refers to an area of an integrated circuit where active or passive components are fabricated. This region can contain structures like transistors, diodes, capacitors, resistors, and memory storage cells. Structurally, the device region can be formed using techniques used in semiconductor manufacturing such as deposition (e.g., chemical vapor deposition (CVD), plasma enhanced CVD, physical deposition, and others), etching, thermal oxidation, photolithography, and the like.

The first substrate 204 forms the structural foundation or base for the first wafer 208. In embodiments, one or more layers of, for example, silicon form the first substrate 204.

In embodiments, the first substrate is formed from silicon, the primary substance used in the semiconductor industry due to its semi-metallic properties that give it the ability to insulate and conduct electricity. When purified in its crystalline form, silicon can be doped with various elements to enhance its conductive properties.

The first substrate 204 establishes a solid and stable base that supports creating and integrating various device regions within the 3D IC 100. It also provides physical resilience to the device region in the wafer, limiting potential damage during the fabrication process and ensuring the longevity of the final product.

In embodiments, vias 106 are formed through a process known as backgrinding, which also doubles as a method for controlling the thickness on the backside of the first wafer 208. By grinding down the backside of the first wafer 208, its thickness is reduced, which advantageously prepares the first wafer 208 for stacking by ensuring the proper formation of the vias 106 and the preservation of the structural integrity of the first wafer 208.

FIG. 2B illustrates the first wafer 208 after applying a photoresist material 210 and the etching of the first device region 102 and the first substrate 204 to form cavity 212 in the first wafer 208. In embodiments, a photoresist material 210 is applied to the top surface of the first wafer 208. In embodiments, a photomask is applied to the surface of the photoresist material 210. In embodiments, the placement of cavity 212 is set to not impact the vias 106.

In embodiments, when reference is made to a cavity, the cavity may be represented as a square moat. In embodiments, the shape of the square moat is concerning a top-view. In embodiments, the square moat is a single connected moat. In embodiments, the cavity or moat surrounds the device and isolation region.

The photoresist material 210 is a light-sensitive compound capable of changing its properties when exposed to ultraviolet light, allowing it to function effectively for photolithography procedures.

The photoresist material 210 is subjected to a photolithographic process that involves applying light (usually ultraviolet). The photomask effectively shields sections of the photoresist material 210 from exposure to light. As a result, the exposed areas of the photoresist material 210 change their chemical composition, allowing it to act as an etch resist. In contrast, the unexposed areas can subsequently be easily removed.

In embodiments, the soluble portions of the photoresist material 210 are removed in a developer solution. This reveals a pattern corresponding to the area illuminated during exposure and replicates the design on the photomask.

After the photoresist material 210 has been patterned appropriately, the resulting structure is ready to be etched. Etching is a process where selective layers of the first device region 102 and the first substrate 204 are removed. This can be done using either wet etching, which uses reactive liquids, or dry etching, which uses reactive gases. The areas of the first device region 102 and the first substrate 204 covered by the photoresist material 210 are protected or “masked” from the etching process, maintaining their initial structure. In contrast, the unmasked areas get removed, resulting in cavity 212.

The strategic positioning of the cavity 212 within the first device region 102 and the first substrate 204 in the first wafer 208 establishes a built-in (i.e., integrated), localized area designated for singulation. This feature facilitates the die's precise extraction and subsequent placement, often called ‘pick and place,’ onto, for example, the second wafer 114 in the 3D IC 100.

FIG. 2C illustrates the first wafer 208 after the photoresist material 210 is removed, a dielectric fill 214 is introduced in cavity 212, and the deposition of a first temporary bonding layer 216.

Following the removal of the photoresist material 210, a dielectric fill 306 is introduced into cavity 212, previously taken up by the first device region 102 and the first substrate 204. The purpose of the dielectric fill 214 is to act as a localized area designated for singulation. It should be noted that although the dielectric fill 214 is illustrated as a complete dielectric fill, a partial dielectric fill is contemplated in embodiments.

Advantageously, the dielectric fill 306 acts as an end-point detection and protects between the chiplets (individual dies) during the singulation process flow.

In embodiments, once cavity 212 is filled with the dielectric fill 214, chemical-mechanical polishing (CMP) is applied to smoothen the top surface utilizing mechanical and chemical means. CMP ensures uniformity and consistency across the surface to prepare it for bonding.

After CMP, the first temporary bonding layer 216 is deposited above the first device region 102 and the exposed areas of the dielectric fill 214, on the top surface of the first wafer 208. The first temporary bonding layer 216 allows for uniform bonding to another surface, as detailed below. The first temporary bonding layer 216 can additionally provide mechanical strength. The first temporary bonding layer 216 can be epoxy-based, polyimide, or the like. The first temporary bonding layer 216 may be coated over the surface of the first wafer 208. In one embodiment, the first temporary bonding layer 216 may be deposited over the surface of the first wafer 208. The first temporary bonding layer 216 may be 0.05 microns thick, for example, 0.03 μm to 0.1 μm, and 0.01 μm to 0.2 μm in one embodiment.

FIG. 2D illustrates a third wafer 218 to be attached to the first wafer 208, as detailed further below. The third wafer 218 includes a third substrate 220 and a second temporary bonding layer 222. The third wafer 218 is placed on the wafer chuck 116. In embodiments, one or more layers of, for example, silicon form the third substrate 220, as discussed concerning the first substrate 204 above. In embodiments, the third wafer 218 is made of a plastic substance. In embodiments, the third wafer 218 is made of a flexible substance.

The third wafer 218 may be 200 microns thick, for example, 50 μm to 300 μm, and 50 μm to 300 μm in one embodiment. The third substrate 220 may be 200 microns thick, for example, 50 μm to 300 μm, and 50 μm to 300 μm in one embodiment. The second temporary bonding layer 222 may 0.05 microns thick, for example, 0.03 μm to 0.1 μm, and 0.01 μm to 0.2 μm in one embodiment.

In embodiments, the third substrate 220 is made of quartz or silicon. In embodiments, the second temporary bonding layer 222 is deposited on the top surface of the third substrate 220. In embodiments, the second temporary bonding layer 222 is the same bonding material as the first temporary bonding layer 216. In embodiments, the second temporary bonding layer 222 is a different material than the first temporary bonding layer 216.

FIG. 2E illustrates the third wafer 218 attached to the first wafer 208 to form a single, cohesive structure. In embodiments, the third wafer 218 is flipped, so the second temporary bonding layer 222 is in contact with the first temporary bonding layer 216.

In embodiments, the first temporary bonding layer 216 is attached or bonded to the second temporary bonding layer 222 through annealing, ultraviolet-assisted bonding, temperature-assisted bonding, plasma-based bonding, fusion bonding, mechanical pressure, or other suitable method or combination of methods.

Annealing and temperature-assisted bonding rely on applying heat to the wafers that can alter a material's physical and sometimes chemical properties to increase its ductility and reduce its hardness, making it more workable. In embodiments, the first wafer 208 and the third wafer 218 are heated to a temperature sufficient for the bonding layers to interact and attach. In embodiments, the heat causes the molecules at the interface of the bonding layers to become more mobile, allowing them to interact and bond more readily.

UV or Ultraviolet-assisted bonding makes use of ultraviolet light during the bonding process. In embodiments, UV light promotes the creation of active chemical species, which react at the interface of the two bonding layers, thereby facilitating their cohesion.

Plasma-based bonding involves using a plasma treatment to clean and activate the surfaces of the wafers. The activated surfaces can then be brought into contact to create a bond. In embodiments, the plasma process is applied to the bonding layers to remove organic contamination and reduce the number of voids at the bonding interface, resulting in a higher-quality bond.

Mechanical pressure is another method used to facilitate bonding. In embodiments, the first wafer 208 and the third wafer 218 are physically pressed together at the bonding layer while applying heat, causing the bonding layers to adhere to each other due to the pressure-induced deformation of the material.

In embodiments, the first wafer 208 and the third wafer 218 do not include a temporary bonding layer. In such embodiments, the wafers are attached using, for example, fusion bonding. Fusion bonding refers to a process where two semiconductor wafers are joined together without using an intermediate adhesive layer. The process occurs under high temperatures and pressures, whereby the atomic force between the wafer surfaces is induced to bond chemically. To achieve an effective bond, the wafer surfaces are highly polished and cleaned to eliminate any impurities or defects that might inhibit the bonding process.

FIG. 2F illustrates the single, cohesive structure after bonding the third wafer 218 to the first wafer 208, flipping the single, cohesive structure on the wafer chuck 116, and reducing the thickness of the first wafer 208 such that it is labeled as first wafer 108. In embodiments, the thickness of the first wafer 108 is reduced to less than 50 micrometers (μm). In embodiments, the thickness of the first wafer 108 is less than 50 micrometers.

In embodiments, the thickness of the first wafer 208 is reduced through a backgrinding process. Backgrinding involves grinding away the first substrate 204 on the exposed side of the single, cohesive structure. In embodiments, the backgrinding process involves a grinding wheel with a definite abrasive grain size, onto which the first substrate 204 is mechanically grinded until it reaches the desired thinness. The grinding wheel rotates while the single, cohesive structure is pressed against it, removing material from the first substrate 204. In embodiments, throughout the process, a continuous stream of cooling lubricant is typically supplied to the grinding interface to prevent temperature elevation and to facilitate the removal of debris.

In embodiments, the surface of the first substrate 104 that has been grinded down, undergoes a post-grinding treatment to remove or reduce mechanical damages, such as surface roughness or micro-cracks. A common post-grinding treatment is chemical mechanical polishing (CMP) or planarization, where the first substrate 104 is polished by chemically reactive liquid while mechanical force is applied.

FIG. 2G illustrates the single, cohesive structure with a first protective layer 224 on the backside of the first wafer 108 and a second protective layer 226 on the top surface of the third wafer 218. The single, cohesive structure is placed on a wafer chuck 116.

The protective layers (i.e., the first protective layer 224 and the second protective layer 226), also known as passivation layers, protect the exposed surfaces of the single, cohesive structure from potential physical damage during handling or packaging.

Different materials can be used for the protective layers, such as silicon dioxide (SiO2), silicon nitride (Si3N4), polyimide, or even layers of metal or ceramic. Silicon compounds like silicon dioxide and silicon nitride are common due to their excellent insulating properties and compatibility with typical semiconductor processes. Polyimide is also frequently used because of its superior mechanical and thermal properties.

In embodiments, the protective layers are deposited onto the wafers through appropriate fabrication processes targeting material deposition. For instance, silicon dioxide or silicon nitride layers can be deposited using chemical vapor deposition (CVD) techniques, while metallization processes can be used for metal layers. Alternatively, spin coating followed by curing is often used for applying a polyimide layer. In embodiments, the protective layers are deposited such that they are uniformly thick and cover the entire surface of the wafer without any voids or defects.

FIG. 2H illustrates the single, cohesive structure with the protective layers after applying a photoresist material 228 on the top surface of the second protective layer 226 and the etching of the second protective layer 226 and the third substrate 220 to form the cavity 230. The single, cohesive structure is placed on a wafer chuck 116.

In embodiments, photoresist material 228 is applied to the top surface of the second protective layer 226. In embodiments, a photomask is applied to the surface of the photoresist material 228. The photoresist material 228 is subjected to a photolithographic process, and the photomask shields sections of the photoresist material 228 from exposure to light. As a result, the exposed areas of the photoresist material 228 change their chemical composition, allowing it to act as an etch resist. In contrast, the unexposed areas can subsequently be easily removed. In embodiments, the soluble portions of the photoresist material 228 are removed in a developer solution. This reveals a pattern corresponding to the area illuminated during exposure and replicates the design on the photomask.

After the photoresist material 228 has been patterned appropriately, selective layers of the second protective layer 226 and the third substrate 220 are removed. The areas of the second protective layer 226 and the third substrate 220 covered by the photoresist material 228 are protected or “masked” from the etching process, maintaining their initial structure. In contrast, the unmasked areas get removed, resulting in cavity 230.

As an alternative to using the photoresist material 228 and the etching process described above to form cavity 230, in embodiments, a mechanical scribe process or a laser beam cut process can be used to form cavity 230 without photoresist. After the etching process, the masking layer can be stripped away through photoresist stripping.

In embodiments, the photoresist material 228 is patterned such that the cavity 230 is vertically aligned with the dielectric fill 214. In embodiments, the cavity 230 is formed to overlap with the dielectric fill 214 in a top view. In embodiments, cavity 230 is formed such that they have an overlapping footprint with the dielectric fill 214. In embodiments, the width/diameter of cavity 230 is less than the width/diameter of the dielectric fill 214. Hence, there is less chance of introducing alignment errors between the cavity 230 and the dielectric fill 214.

FIG. 2I illustrates the next step in the process flow, where the single, cohesive structure is flipped on the wafer chuck 116, the dielectric fill 214 is removed, and the removal is extended through the first temporary bonding layer 216 and the second temporary bonding layer 222 in the open cavity region.

In embodiments, the dielectric fill 214 is removed through a mask less process using selective etching, such as wet or dry etching. Wet etching involves using liquid chemicals or etchants, which react with the dielectric material to remove it from certain areas. Dry etching, such as Reactive-Ion Etching (RIE) or Deep Reactive Ion Etching (DRIE), uses ionized gases or plasma to etch away the dielectric material. In embodiments, a masking layer, such as a photoresist, is applied on the first protective layer 224, where the etching is not desired. This mask protects the underlying areas during the etching process while the dielectric fill 214 is removed. After the etching process, the masking layer can be stripped away through photoresist stripping.

The etching process is extended at the location of the dielectric fill 214 such that the first temporary bonding layer 216 and the second temporary bonding layer 222 are also removed to form a cavity 232 extending from the top surface of the first protective layer 224 to the top surface of the third substrate 220.

FIG. 2J illustrates the final step in the process flow, where the single, cohesive structure, including the first wafer 108 and the third wafer 218, is flipped and placed on a curved surface 202 for die singulation. In embodiments, the first protective layer 224 is removed before die singulation.

Die singulation or dicing separates individual dies or chiplets from a silicon wafer using the “mechanical stress-induced method,” also known as “die pick-up” or the “flex method.” The first wafer 108, attached to the third wafer 218, is placed onto a curved surfaced 202 (or contoured surface or a flexible substrate). The curved surface can be adjusted depending on the desired fracture lines. Once it's set on this curved surface, pressure is applied.

When pressure is applied, the curvature of the surface exerts a controlled stress on the first wafer 108 and the third wafer 218. As silicon is a brittle material, it breaks easily along the pre-scribed lines (these lines represent the boundaries between the individual dies or chiplets) at cavity 232. The tensile stress generated by the bending leads to the initiation and propagation of cracks along these stress lines, causing the first wafer 108 to separate into individual dies or chiplets.

After the singulation process, individual dies or chiplets are picked up by automated equipment for placement on top of the lower die, such as the second wafer 114, as illustrated in FIG. 1. This pick-and-place process uses automated machines to ensure accuracy and prevent chip damage.

In embodiments, a laser beam is used to decouple the sacrificial, third substrate 220 after the placement of the individual dies or chiplets. In embodiments, an infrared source is used to lift the disposable, third substrate 220 after the placement of the individual dies or chiplets. In embodiments, the infrared source is selected based on the disposable, third substrate 220 material type. It should be appreciated that the sacrificial, third substrate 220 does not need to be removed after placement on the base circuit.

A chiplet refers to a generally thin circuit composed of native connections between the device region and the substrate of the first wafer 108. In embodiments, the thickness of the chiplet is limited to less than 40 microns. Chiplets differ from the individual dies that originate from the typically thick wafer of, for example, 500 microns separated from the original wafer using the typical scoring and cracking processes.

In embodiments, the chiplets are directly (i.e., hybrid) coupled to the electrical components of the underlying base circuit, such as the second wafer 114, without using the traditional intervening packaging material, such as solder bonding or intermediary interposers. In such embodiments, the metal surface of a metal pad on one die is directly attached to the exposed metal surface of a metal pad on a second die.

In embodiments, the second protective layer 226, the third wafer 218—including the bonding layer formed by the first temporary bonding layer 216 and the second temporary bonding layer 222 are removed after the singulation process and pick and place to expose the top surface of the first device region 102 of the first wafer 108.

In embodiments, the process flow, as detailed in steps 2A-2J, is replicated to add chiplets to existing chiplets to create the N chiplet, stacked together, vertically integrated 3D IC 100. In embodiments, every step from 2A-2J is replicated to stack a chiplet on an existing chiplet to create the N chiplet.

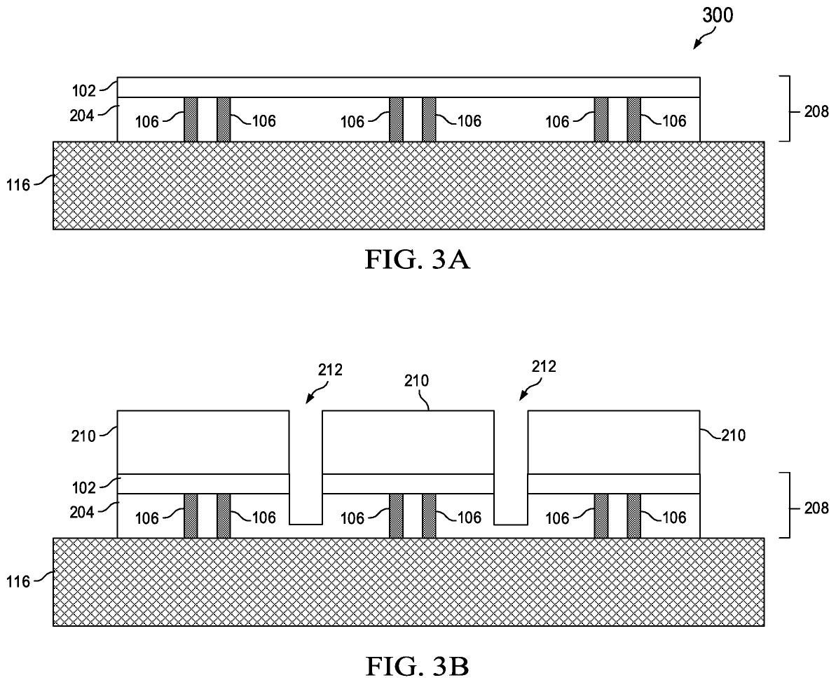

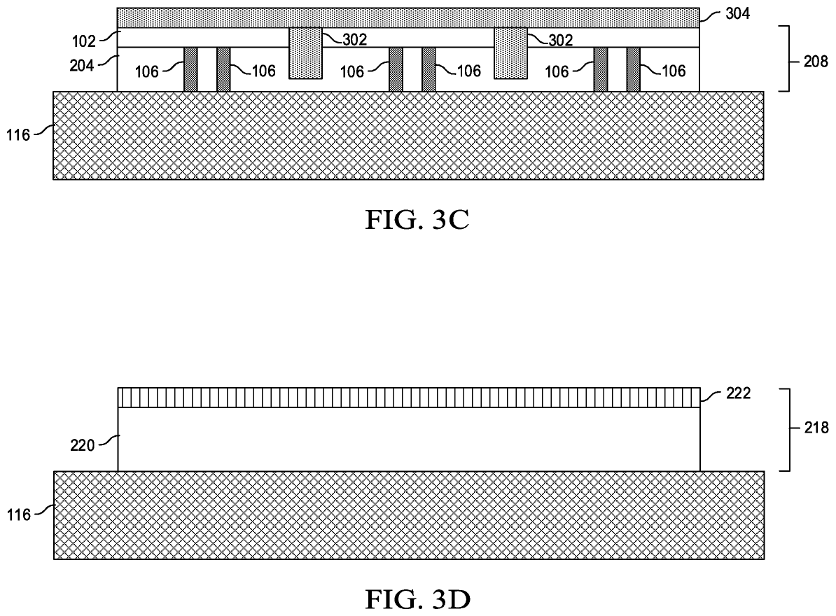

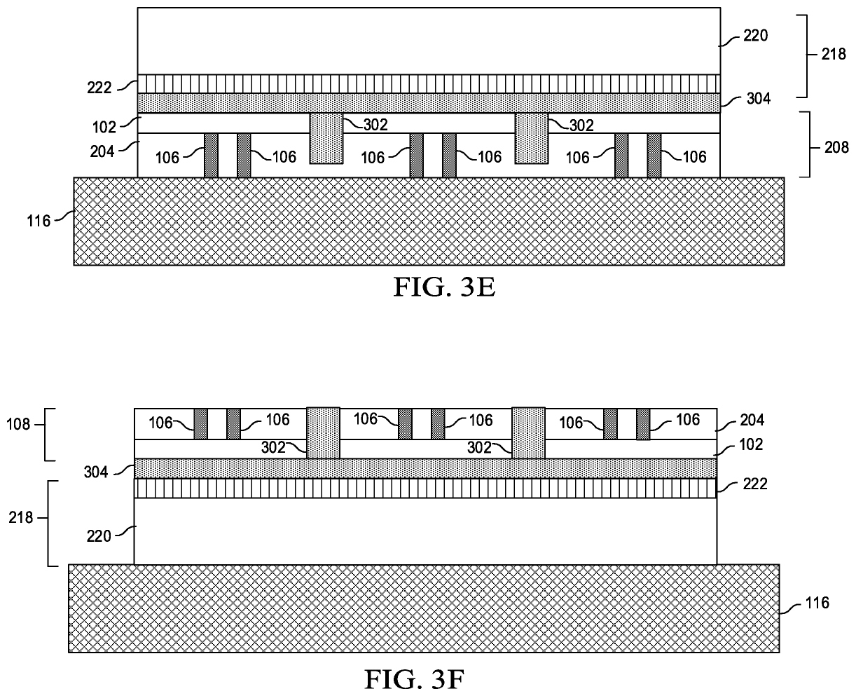

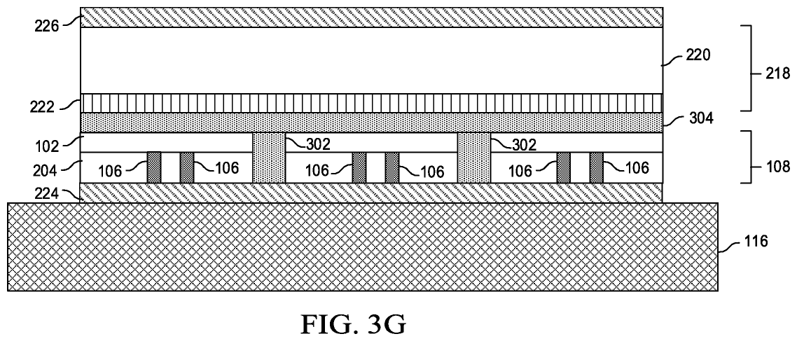

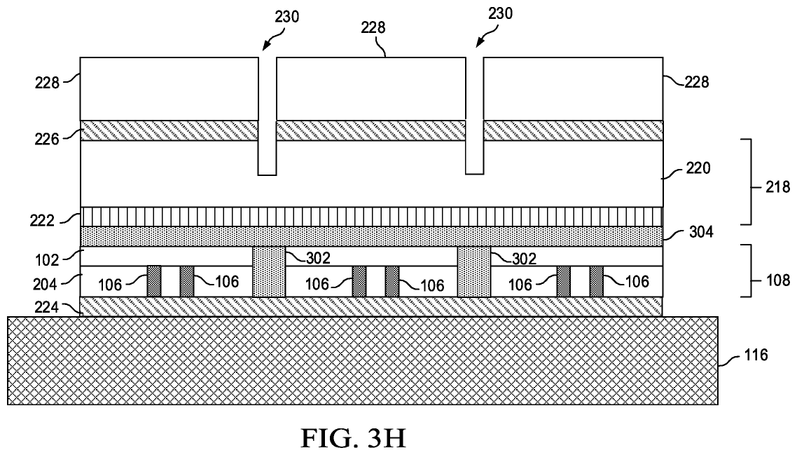

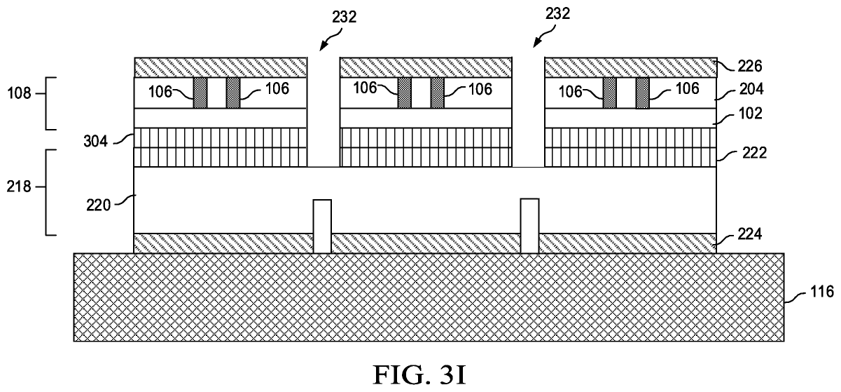

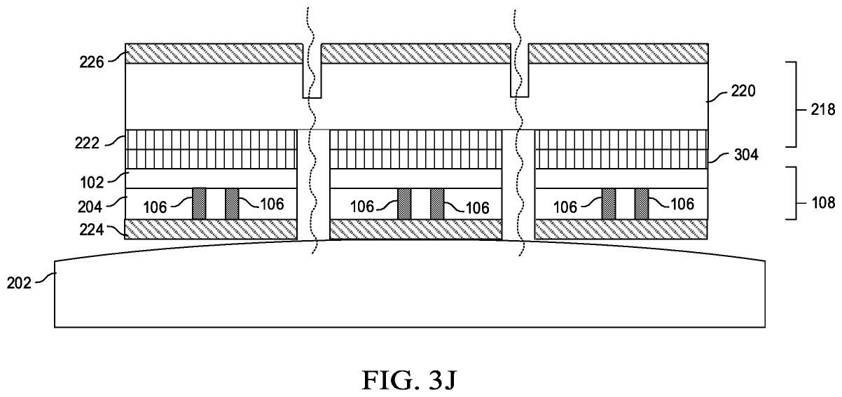

FIGS. 3A-J illustrate cross-sectional views of an alternative embodiment process flow for forming the 3D IC 100. The example flow details the process that facilitates die separation and the sequential pick and place of device circuits for advanced multi-level circuit attachments employing a cavity filled with bonding material.

FIG. 3A illustrates the first wafer 208, positioned atop the wafer chuck 116, akin to the first wafer 208 depicted in FIG. 2A. In certain embodiments, the structuring and functionality of the first wafer 208 mirror those in FIG. 2A. Therefore, to avoid redundancy and maintain brevity, the specifics of the first wafer 208 are not reiterated.

FIG. 3B illustrates the first wafer 208 after applying a photoresist material 210 and the etching of the first device region 102 and the first substrate 204 to form cavity 212, similar to the solitary structure 200 depicted in FIG. 2A, which are not duplicated to avoid redundancy and maintain brevity.

The strategic positioning of cavity 212 within the first device region 102 and the first substrate 204 in the first wafer 208 establishes an integrated, localized area designated for singulation. This feature facilitates the die's precise extraction and subsequent placement, often called ‘pick and place,’ onto, for example, the second wafer 114 in the 3D IC 100.

FIG. 3C illustrates the first wafer 208 after the photoresist material 210 is removed, and a first temporary bonding material 302 is deposited into the cavity region and on the top surface of the first device region 102.

Following the removal of the photoresist material 210, the first temporary bonding material 302 is deposited into the cavity 212, previously taken up by the first device region 102 and the first substrate 204. The purpose of the cavity 212 is to act as a localized area designated for singulation. It should be noted that although the first temporary bonding material 302 within cavity 212 is illustrated as a complete fill, a partial fill is contemplated in embodiments.

Advantageously, the first temporary bonding material 302 acts as an end-point detection and protects in-between the chiplets (individual dies) during the singulation process flow.

In embodiments, once the first temporary bonding material 302 is deposited into cavity 212, chemical-mechanical polishing (CMP) is applied to smoothen the top surface utilizing mechanical and chemical means. CMP ensures uniformity and consistency across the surface to prepare it for bonding.

After CMP, a first temporary bonding layer 304 is deposited above the first device region 102, on the top surface of the first wafer 208. The first temporary bonding layer 304 allows for uniform bonding to another surface, as detailed below. The first temporary bonding layer 304 can additionally provide mechanical strength. The first bonding material and the first temporary bonding layer 304 can be silicon dioxide, silicon nitride, polyimide, or the like.

FIG. 3D illustrates a third wafer 218 to be attached to the first wafer 208, akin to the attachment detailed in FIG. 2D. Therefore, to avoid redundancy and maintain brevity, the specifics of the attachment are not reiterated.

FIG. 3E illustrates the third wafer 218 attached to the first wafer 208 to form a single, cohesive structure, similar to the attachment detailed in FIG. 2E. In embodiments, the third wafer 218 is flipped, so the second temporary bonding layer 222 is in contact with the first temporary bonding layer 304.

In embodiments, the first temporary bonding layer 304 is attached or bonded to the second temporary bonding layer 222 through annealing, ultraviolet-assisted bonding, temperature-assisted bonding, plasma-based bonding, mechanical pressure, or other suitable method or combination of methods.

FIG. 3F illustrates the single, cohesive structure after bonding the third wafer 218 to the first wafer 108, flipping the single, cohesive structure on the wafer chuck 116, and reducing the thickness of the first wafer 208 such that it is labeled as first wafer 108, as detailed in FIG. 2F. In embodiments, the thickness of the first wafer 108 is reduced to less than 50 micrometers (μm).

FIG. 3G illustrates the single, cohesive structure with a first protective layer 224 on the backside of the first wafer 108 and a second protective layer 226 on the top surface of the third wafer 218, as detailed in FIG. 2G. The single, cohesive structure is placed on a wafer chuck 116.

FIG. 3H illustrates the single, cohesive structure with the protective layers after applying a photoresist material 228 on the top surface of the second protective layer 226 and the etching of the second protective layer 226 and the third substrate 220 to form the cavity 230, as detailed in FIG. 2H. The single, cohesive structure is placed on a wafer chuck 116.

FIG. 3I illustrates the next step in the process flow, where the single, cohesive structure is flipped on the wafer chuck 116, the first temporary bonding material 302 at the cavity 212 is removed, and the removal is extended through the first temporary bonding layer 304 and the second temporary bonding layer 222 in the open cavity region.

In embodiments, the first temporary bonding material 302 at the cavity 212 is removed through selective etching, such as wet or dry etching, similar to the removal of the dielectric fill 214 in FIG. 2I.

The etching process is extended at the location of the cavity 212 such that the first temporary bonding layer 304 and the second temporary bonding layer 222 are also removed to form the cavity 232 extending from the top surface of the first protective layer 224 to the top surface of the third substrate 220.

FIG. 3J illustrates the final step in the process flow, where the single, cohesive structure, including the first wafer 108 and the third wafer 218, is flipped and placed on a curved surface 202 for die singulation, as detailed in FIG. 2J. In embodiments, the first protective layer 224 is removed before die singulation.

The first wafer 108, attached to the third wafer 218, is placed onto the curved surfaced 202 (or contoured surface or a flexible substrate). The curved surface can be adjusted depending on the desired fracture lines. Once it's set on this curved surface, pressure is applied.

When pressure is applied, the curvature of the surface exerts a controlled stress on the first wafer 108 and the third wafer 218. As silicon is a brittle material, it breaks easily along the pre-scribed lines (these lines represent the boundaries between the individual dies or chiplets) at cavity 232. The tensile stress generated by the bending leads to the initiation and propagation of cracks along these stress lines, causing the first wafer 108 to separate into individual dies or chiplets.

After the singulation process, individual dies or chiplets are picked up by automated equipment for placement on top of the lower die, such as the second wafer 114, as illustrated in FIG. 1. This pick-and-place process uses automated machines to ensure accuracy and prevent chip damage.

In embodiments, the second protective layer 226, the third wafer 218—including the bonding layer formed by the first temporary bonding layer 216 and the second temporary bonding layer 222 are removed after the singulation process to expose the top surface of the first device region 102 of the first wafer 108, as discussed with respect to FIG. 2J.

In embodiments, the process flow, as detailed in steps 3A-3J, is replicated to add chiplets to existing chiplets to create the N height, vertically integrated 3D IC 100.

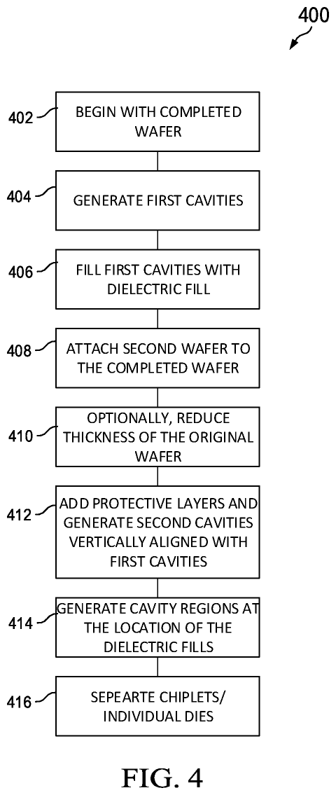

FIG. 4 illustrates a flow chart of an embodiment method 400 that details the process that facilitates die separation and the sequential pick and place of device circuits for advanced multi-level circuit attachments employing a cavity filled with dielectric.

At step 402, the process begins with a completed wafer. The completed wafer includes a plurality of to-be die or chiplets. In embodiments, the top surface of the completed wafer includes metal. In embodiments, the completed wafer includes back via connections or extensions from the device region on the top surface to the backside of the completed wafer at the substrate. In embodiments, the completed wafer is back grinded to reduce the thickness of the silicon. In embodiments, the thickness of the wafer is reduced using backside wafer thickness reduction.

At step 404, the first cavity is generated from the completed wafer's top surface through the wafer's substrate. In embodiments, the first cavity helps to establish an integrated, localized area designated for singulation of the to-be die or chiplets.

At step 406, dielectric fill is used to fill out the first cavity generated at step 404 fully or partially. In embodiments, a CMP process ensures uniformity and consistency across the surface to prepare it for bonding. A bonding layer is deposited over the top surface of the wafer after the dielectric fill.

At step 408, a sacrificial/temporary wafer with a bonding layer deposited on its top surface is attached to the completed wafer at the bonding layers. The attached wafers form a cohesive structure through the attachment.

At step 410, optionally, the thickness of the completed wafer is reduced through its backside to reach the desired thickness.

At step 412, a protective layer is placed on the top surface and the backside of the cohesive structure. Second cavity are generated vertically aligned with the positions of the dielectric fill in the original wafer. In embodiments, the second cavity are etched using a photoresist material and mask. In embodiments, the cavity are mechanically scribed or cut using a laser beam.

At step 414, cavity regions are etched/cut from the top surface of the device region at the locations of the dielectric fills, which are extended vertically through the bonding layers.

At step 416, the structure is placed on a curved surface, and pressure is applied to separate the chipsets/individual dies. The protective layers are removed, and the individual dies/chiplets are pick and placed on a third wafer to create a three-dimensional integrated circuit.

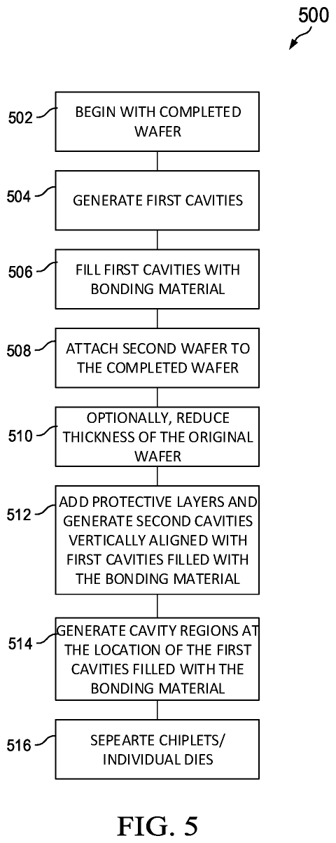

FIG. 5 illustrates a flow chart of an embodiment method 500 that details the process that facilitates die separation and the sequential pick and place of device circuits for advanced multi-level circuit attachments employing a cavity filled with bonding material.

At step 502, the process begins with a completed wafer. The completed wafer includes a plurality of to-be die or chiplets. In embodiments, the top surface of the completed wafer includes metal. In embodiments, the completed wafer includes back via connections or extensions from the device region on the top surface to the backside of the completed wafer at the substrate. In embodiments, the completed wafer is back grinded to reduce the thickness of the silicon. In embodiments, the thickness of the wafer is reduced using backside wafer thickness reduction.

At step 504, a photoresist and mask are used to generate a cavity from the completed wafer's top surface through the wafer's substrate. In embodiments, the cavity helps to establish an integrated, localized area designated for singulation of the to-be die or chiplets.

At step 506, a bonding material is used to fill out the cavity generated at step 504 fully or partially. In embodiments, a CMP process ensures uniformity and consistency across the surface to prepare it for bonding. A bonding layer is deposited over the top surface of the wafer after the bonding material fills the cavity.

At step 508, a sacrificial/temporary wafer with a bonding layer deposited on its top surface is attached to the completed wafer at the bonding layers. The attached wafers form a cohesive structure through the attachment.

At step 510, optionally, the thickness of the completed wafer is reduced through its backside to reach the desired thickness.

At step 512, a protective layer is placed on the top surface and the backside of the cohesive structure. Cavities are generated vertically aligned with the positions of the bonding material at the cavity from step 504 in the original wafer. In embodiments, the cavity is etched using a photoresist material and mask. In embodiments, the cavity is mechanically scribed or cut using a laser beam.

At step 514, cavity regions are etched/cut from the top surface of the device region at the locations of the bonding material at the cavity from step 504, which are extended vertically through the bonding layers.

At step 516, the structure is placed on a curved surface, and pressure is applied to separate the chipsets/individual dies. The protective layers are removed, and the individual dies/chiplets are pick and placed on a third wafer to create a three-dimensional integrated circuit.

It is noted that all steps outlined in the flow charts of the method are not necessarily required and can be optional. Further, changes to the arrangement of the steps, removal of one or more steps and path connections, and addition of steps and path connections are similarly contemplated.

A first aspect relates to a method for assembling a package. The method includes forming first cavities in a first wafer comprising a device region formed on a first substrate, the first substrate having a plurality of vias coupling the device region to an exposed surface of the first substrate, the first cavities establishing a localized area designated for singulation of the first wafer; filling the first cavities with a dielectric fill; depositing a bonding layer on the exposed surface of the device region; attaching a sacrificial wafer to the first wafer at the bonding layer, the sacrificial wafer comprising a second substrate; attaching protective layers to the exposed surface of the first substrate and the exposed surface of the sacrificial wafer; forming second cavities at the exposed surface of the sacrificial wafer, the second cavities partially extending through the second substrate with an overlapping footprint with the first cavities; forming third cavities at the first cavities to remove the dielectric fill and extending the third cavities to a cavity region at the bonding layer; and placing the first wafer attached to the sacrificial wafer on a curved surface and applying pressure on the first wafer to form chiplets, each chiplet comprising individual dies from the first wafer.

In a first implementation form of the method according to the first aspect as such, the method further includes reducing a thickness of the exposed surface of the first substrate after attaching the sacrificial wafer to the first wafer.

In a second implementation form of the method according to the first aspect as such or any preceding implementation form of the first aspect, the method further includes removing the protective layers, the sacrificial wafer, and bonding layer after forming the chiplets. The sacrificial wafer is decoupled from the chiplets using a laser beam or removed from the chiplets using an infrared source.

In a third implementation form of the method according to the first aspect as such or any preceding implementation form of the first aspect, the chiplets are to be pick-and-placed on to a base circuit to form a three-dimensional integrated circuit. The base circuit is a microprocessor or a three-dimensional memory stack.

In a fourth implementation form of the method according to the first aspect as such or any preceding implementation form of the first aspect, the filling of the first cavities includes completely filling the first cavities with the dielectric fill, or partially filling the first cavities with the dielectric fill.

In a fifth implementation form of the method according to the first aspect as such or any preceding implementation form of the first aspect, the vias are Through-Silicon Vias (TSVs) used to vertically interconnect a chiplet to a base circuit after the chiplet is placed on the base circuit.

In a sixth implementation form of the method according to the first aspect as such or any preceding implementation form of the first aspect, the first cavities, the second cavities, and the third cavities are formed using a photoresist material and a photomask, laser etching, mechanical scribing, or a combination thereof.

A second aspect relates to a method for chiplet separation. The method includes forming first cavities in a first wafer comprising a device region formed on a first substrate, the first substrate having a plurality of vias coupling the device region to an exposed surface of the first substrate, the first cavities establishing a localized area designated for singulation of the first wafer; filling the first cavities with a bonding material; depositing a bonding layer on the exposed surface of the device region; attaching a sacrificial wafer to the first wafer at the bonding layer, the sacrificial wafer comprising a second substrate; attaching protective layers to the exposed surface of the first substrate; forming second cavities at the exposed surface of the sacrificial wafer, the second cavities partially extending through the second substrate, the second cavities vertically aligned with the first cavities; forming third cavities at the first cavities to remove the bonding material and extending the third cavities to a cavity region at the bonding layer; and separating portions of the first substrate into chiplets, each chiplet defined by the third cavities and supported by a corresponding portion of the sacrificial wafer.

In a first implementation form of the method according to the second aspect as such, the method further includes reducing a thickness of the exposed surface of the first substrate after attaching the sacrificial wafer to the first wafer.

In a second implementation form of the method according to the second aspect as such or any preceding implementation form of the second aspect, the method further includes placing the first wafer attached to the sacrificial wafer on a curved surface and applying pressure on the first wafer to form chiplets, each chiplet comprising individual dies from the first wafer; and removing the protective layers, the sacrificial wafer, and bonding layer after forming the chiplets, wherein the sacrificial wafer is decoupled from the chiplets using a laser beam or removed from the chiplets using an infrared source.

In a third implementation form of the method according to the second aspect as such or any preceding implementation form of the second aspect, the method further includes placing the first wafer attached to the sacrificial wafer on a curved surface and applying pressure on the first wafer to form chiplets, each chiplet comprising individual dies from the first wafer; and stacking the chiplets on to a base circuit to form a three-dimensional integrated circuit, and wherein the base circuit is a microprocessor or a three-dimensional memory stack.

In a fourth implementation form of the method according to the second aspect as such or any preceding implementation form of the second aspect, the filling of the first cavities includes completely filling the first cavities with the bonding material, or partially filling the first cavities with the bonding material.

In a fifth implementation form of the method according to the second aspect as such or any preceding implementation form of the second aspect, the method further includes placing the first wafer attached to the sacrificial wafer on a curved surface and applying pressure on the first wafer to form chiplets, each chiplet comprising individual dies from the first wafer, wherein the vias are Through-Silicon Vias (TSVs) that vertically interconnect a chiplet to a base circuit after the chiplet is placed on the base circuit.

In a sixth implementation form of the method according to the second aspect as such or any preceding implementation form of the second aspect, the first cavities, the second cavities, and the third cavities are formed using a photoresist material and a photomask, laser etching, mechanical scribing, or a combination thereof.

A third aspect relates to a semiconductor structure. The semiconductor structure includes a first wafer comprising a device region, a first substrate, and a first bonding layer, the first substrate arranged in between the device region and the first bonding layer, the first substrate having a plurality of vias coupling the device region to a surface of the first substrate attached to the first bonding layer, the first wafer having first cavities establishing a localized area designated for singulation of the first wafer; a sacrificial wafer comprising a second substrate and a second bonding layer, the second bonding layer attached to the first bonding layer of the first wafer, the first cavities extending through the second bonding layer of the sacrificial wafer; a first protective layer attached to the device region of the first wafer, the first cavities extending through the first protective layer; a second protective layer attached to the sacrificial wafer at the second substrate; and second cavities vertically aligned with the first cavities, the second cavities extending through the second protective layer and partially through the second substrate.

In a first implementation form of the semiconductor structure according to the third aspect as such, wherein, after placing the semiconductor structure on a curved surface and applying pressure, the semiconductor structure is split into a plurality of chiplets to be attached to a base circuit to form a three-dimensional integrated circuit.

In a second implementation form of the semiconductor structure according to the third aspect as such or any preceding implementation form of the third aspect, the vias are Through-Silicon Vias (TSVs) used to vertically interconnect each chiplet to the base circuit after being placed on the base circuit.

In a third implementation form of the semiconductor structure according to the third aspect as such or any preceding implementation form of the third aspect, the first protective layer, the second protective layer, the sacrificial wafer, and the first bonding layer are removed after the semiconductor structure is split into the plurality of chiplets. The sacrificial wafer is removed using a laser beam or an infrared source.

In a fourth implementation form of the semiconductor structure according to the third aspect as such or any preceding implementation form of the third aspect, the base circuit is a microprocessor or a three-dimensional memory stack.

In a fifth implementation form of the semiconductor structure according to the third aspect as such or any preceding implementation form of the third aspect, each of the first cavities and second cavities are formed using a photoresist material and a photomask, laser etching, mechanical scribing, or a combination thereof.

A fourth aspect relates to a method for bonding a chiplet to a device structure. The method includes forming first cavities in a first wafer comprising a device region formed on a first substrate, the first substrate having a plurality of vias coupling the device region to an exposed surface of the first substrate, the first cavities establishing a localized area designated for singulation of the first wafer; filling the first cavities with a dielectric material or a bonding material; depositing a bonding layer on the exposed surface of the device region; attaching a sacrificial wafer to the first wafer at the bonding layer, the sacrificial wafer comprising a second substrate; forming second cavities at the exposed surface of the sacrificial wafer, the second cavities partially extending through the second substrate, the second cavities vertically aligned with the first cavities; forming third cavities at the first cavities to remove the dielectric material or the bonding material and extending the third cavities to a cavity region at the bonding layer; separating portions of the first substrate into chiplets, each chiplet defined by the third cavities and supported by a corresponding portion of the sacrificial wafer; stacking a chiplet on to the device structure to form a three-dimensional integrated circuit; and removing the sacrificial wafer and bonding layer after forming the chiplet, wherein the sacrificial wafer is decoupled from the chiplet using a laser beam or removed from the chiplet using an infrared source.

In a first implementation form of the method according to the fourth aspect as such, the method further includes reducing a thickness of the exposed surface of the first substrate after attaching the sacrificial wafer to the first wafer.

In a second implementation form of the method according to the fourth aspect as such or any preceding implementation form of the fourth aspect, the filling of the first cavities includes completely filling the first cavities with the dielectric fill or the bonding material, or partially filling the first cavities with the dielectric fill or the bonding material.

In a third implementation form of the method according to the fourth aspect as such or any preceding implementation form of the fourth aspect, the vias are Through-Silicon Vias (TSVs) that vertically interconnect the chiplet to the device structure after the chiplet is placed on the device structure.

In a fourth implementation form of the method according to the fourth aspect as such or any preceding implementation form of the fourth aspect, the method further includes placing the first wafer attached to the sacrificial wafer on a curved surface and applying pressure on the first wafer to form the chiplet.

In a fifth implementation form of the method according to the fourth aspect as such or any preceding implementation form of the fourth aspect, the method further includes attaching protective layers to the exposed surface of the first substrate before forming the second cavities and after attaching the sacrificial layer.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A method for assembling a package, the method comprising:
forming first cavities in a first wafer comprising a device region formed on a first substrate, the first substrate having a plurality of vias coupling the device region to an exposed surface of the first substrate, the first cavities establishing a localized area designated for singulation of the first wafer;
filling the first cavities with a dielectric fill;
depositing a bonding layer on the exposed surface of the device region;
attaching a sacrificial wafer to the first wafer at the bonding layer, the sacrificial wafer comprising a second substrate;
attaching protective layers to the exposed surface of the first substrate and the exposed surface of the sacrificial wafer;
forming second cavities at the exposed surface of the sacrificial wafer, the second cavities partially extending through the second substrate with an overlapping footprint with the first cavities;
forming third cavities at the first cavities to remove the dielectric fill and extending the third cavities to a cavity region at the bonding layer; and
placing the first wafer attached to the sacrificial wafer on a curved surface and applying pressure on the first wafer to form chiplets, each chiplet comprising individual dies from the first wafer.

2. The method of claim 1, further comprising reducing a thickness of the exposed surface of the first substrate after attaching the sacrificial wafer to the first wafer.

3. The method of claim 1, further comprising removing the protective layers, the sacrificial wafer, and bonding layer after forming the chiplets, and wherein the sacrificial wafer is decoupled from the chiplets using a laser beam or removed from the chiplets using an infrared source.

4. The method of claim 1, further comprising stacking the chiplets on to a base circuit to form a three-dimensional integrated circuit, and wherein the base circuit is a microprocessor or a three-dimensional memory stack.

5. The method of claim 1, wherein the filling of the first cavities comprises:
completely filling the first cavities with the dielectric fill, or
partially filling the first cavities with the dielectric fill.

6. The method of claim 1, wherein the vias are Through-Silicon Vias (TSVs) used to vertically interconnect a chiplet to a base circuit after the chiplet is placed on the base circuit.

7. The method of claim 1, wherein the first cavities, the second cavities, and the third cavities are formed using a photoresist material and a photomask, laser etching, mechanical scribing, or a combination thereof.

8. A method for chiplet separation, the method comprising:
forming first cavities in a first wafer comprising a device region formed on a first substrate, the first substrate having a plurality of vias coupling the device region to an exposed surface of the first substrate, the first cavities establishing a localized area designated for singulation of the first wafer;
filling the first cavities with a bonding material;
depositing a bonding layer on the exposed surface of the device region;
attaching a sacrificial wafer to the first wafer at the bonding layer, the sacrificial wafer comprising a second substrate;
attaching protective layers to the exposed surface of the first substrate;
forming second cavities at the exposed surface of the sacrificial wafer, the second cavities partially extending through the second substrate, the second cavities vertically aligned with the first cavities;
forming third cavities at the first cavities to remove the bonding material and extending the third cavities to a cavity region at the bonding layer; and
separating portions of the first substrate into chiplets, each chiplet defined by the third cavities and supported by a corresponding portion of the sacrificial wafer.

9. The method of claim 8, further comprising reducing a thickness of the exposed surface of the first substrate after attaching the sacrificial wafer to the first wafer.

10. The method of claim 8, further comprising:
placing the first wafer attached to the sacrificial wafer on a curved surface and applying pressure on the first wafer to form chiplets, each chiplet comprising individual dies from the first wafer; and
removing the protective layers, the sacrificial wafer, and bonding layer after forming the chiplets, wherein the sacrificial wafer is decoupled from the chiplets using a laser beam or removed from the chiplets using an infrared source.

11. The method of claim 8, further comprising:
placing the first wafer attached to the sacrificial wafer on a curved surface and applying pressure on the first wafer to form chiplets, each chiplet comprising individual dies from the first wafer; and
stacking the chiplets on to a base circuit to form a three-dimensional integrated circuit, and wherein the base circuit is a microprocessor or a three-dimensional memory stack.

12. The method of claim 8, wherein the filling of the first cavities comprises:
completely filling the first cavities with the bonding material; or
partially filling the first cavities with the bonding material.

13. The method of claim 8, further comprising placing the first wafer attached to the sacrificial wafer on a curved surface and applying pressure on the first wafer to form chiplets, each chiplet comprising individual dies from the first wafer, wherein the vias are Through-Silicon Vias (TSVs) that vertically interconnect a chiplet to a base circuit after the chiplet is placed on the base circuit.

14. The method of claim 8, wherein the first cavities, the second cavities, and the third cavities are formed using a photoresist material and a photomask, laser etching, mechanical scribing, or a combination thereof.

15. A method for bonding a chiplet to a device structure, the method comprising:
forming first cavities in a first wafer comprising a device region formed on a first substrate, the first substrate having a plurality of vias coupling the device region to an exposed surface of the first substrate, the first cavities establishing a localized area designated for singulation of the first wafer;
filling the first cavities with a dielectric material or a bonding material;
depositing a bonding layer on the exposed surface of the device region;
attaching a sacrificial wafer to the first wafer at the bonding layer, the sacrificial wafer comprising a second substrate;
forming second cavities at the exposed surface of the sacrificial wafer, the second cavities partially extending through the second substrate, the second cavities vertically aligned with the first cavities;
forming third cavities at the first cavities to remove the dielectric material or the bonding material and extending the third cavities to a cavity region at the bonding layer;
separating portions of the first substrate into chiplets, each chiplet defined by the third cavities and supported by a corresponding portion of the sacrificial wafer;
stacking a chiplet on to the device structure to form a three-dimensional integrated circuit; and
removing the sacrificial wafer and bonding layer after forming the chiplet, wherein the sacrificial wafer is decoupled from the chiplet using a laser beam or removed from the chiplet using an infrared source.

16. The method of claim 15, further comprising reducing a thickness of the exposed surface of the first substrate after attaching the sacrificial wafer to the first wafer.

17. The method of claim 15, wherein the filling of the first cavities comprises:
completely filling the first cavities with the dielectric fill or the bonding material; or
partially filling the first cavities with the dielectric fill or the bonding material.

18. The method of claim 15, wherein the vias are Through-Silicon Vias (TSVs) that vertically interconnect the chiplet to the device structure after the chiplet is placed on the device structure.

19. The method of claim 15, further comprising placing the first wafer attached to the sacrificial wafer on a curved surface and applying pressure on the first wafer to form the chiplet.

20. The method of claim 15, further comprising attaching protective layers to the exposed surface of the first substrate before forming the second cavities and after attaching the sacrificial layer.
